(19) United States
(12) Patent Application Publication
(10) Pub. No.: US 2011/0181585 A1
(43) Pub. Date: Jul. 28, 2011

(54) SEMICONDUCTOR DEVICE AND DRIVING METHOD THEREOF, ELECTRO-OPTICAL DEVICE, AND ELECTRONIC DEVICE

(75) Inventors: Tokuro OZAWA, Suwa (JP); Takashi SATO, Chino (JP)

(73) Assignee: SEIKO EPSON CORPORATION, Tokyo (JP)

(21) Appl. No.: 13/013,273

(22) Filed: Jan. 25, 2011

(30) Foreign Application Priority Data
Jan. 26, 2010 (JP) 2010-014360

(51) Int. Cl. G09G 5/00; H03K 17/687

(52) U.S. Cl. 345/213; 327/109

(57) ABSTRACT

A semiconductor device includes: a first transistor which is electrically connected between a capacitive element and a data line; a second transistor which is electrically connected between the first transistor and the capacitive element; and a driving unit. The driving unit drives the first and second transistors so that when the data voltage is applied to the capacitive element, both the first and second transistors are turned on, the second transistor is temporarily turned off, after a timing at which both the first and second transistors are turned on, and then turned on again, and the first transistor is turned off at the timing at which the second transistor is temporarily turned off or after the timing and before the second transistor is turned on again.

### CROSS-REFERENCE TO RELATED APPLICATION

This application is based on and claims priority from Japanese Patent Application No. 2010-014360, filed on Jan. 26, 2010, the contents of which are incorporated herein by reference.

### BACKGROUND

1. Technical Field

The present invention relates to the technical field of a semiconductor device and a driving method thereof, an electro-optical device, and an electronic device.

2. Related Art

A liquid crystal apparatus in an active matrix drive type is an example of a semiconductor device. In the liquid crystal apparatus, a pixel electrode is provided for each pixel on a substrate, and scanning lines, data lines, and thin film transistors (TFT) as pixel switching elements are included for selectively driving the pixel electrodes, thereby realizing active matrix driving.

In such liquid crystal apparatus, due to a parasitic capacitance between a gate and a drain of a TFT as a pixel switching element or between the gate and a source thereof, a feed-through voltage is generated, and there is a technical problem in that a data voltage to be applied to a liquid crystal element which is a capacitive element may be insufficient.

For example, in Japanese Patent No. 3656179, there is proposed a technique in which a main TFT and a sub-TFT having a size greater than that of the main TFT are provided for each pixel. A voltage is supplied to a pixel electrode via the sub-TFT, and thereafter the voltage is supplied to the pixel electrode via the main TFT, thereby reducing a parasitic capacitance of the main TFT.

However, in the technique disclosed in Japanese Patent No. 3656179, there are problems in that it is difficult to reduce variations in parasitic capacitance caused by variations in production of TFTs, and variations in feed-through voltage may remain. Accordingly, there is a concern that a data voltage may be insufficiently applied to a liquid crystal element which is a capacitive element.

### SUMMARY

An advantage of some aspects of the invention is that it provides a semiconductor device capable of applying a data voltage to a capacitive element via a TFT more reliably and a driving method thereof, an electro-optical device and an electronic device having the semiconductor device.

According to an aspect of the invention, there is provided a semiconductor device including: a capacitive element; a data line to which a data voltage to be applied to the capacitive element is applied; a first transistor which is electrically connected between the capacitive element and the data line; a second transistor which is electrically connected between the first transistor and the capacitive element; and a driving unit which drives the first and second transistors so that when the data voltage is applied to the capacitive element, both the first and second transistors are turned on, the second transistor is temporarily turned off, after a timing at which both the first and second transistors are turned on, and then turned on again, and the first transistor is turned off at the same timing at which the second transistor is temporarily turned off or after the timing and before the second transistor is turned on again.

In this configuration, for example, the first and second transistors which are connected to each other in series are provided between the capacitive element (that is, having a capacitive property) and the data line. The capacitive element is a capacitor, a transistor, a liquid crystal element, an organic electro-luminescence (EL) element, or an electrophoretic element. A source of the first transistor is electrically connected to the data line, a drain of the first transistor is electrically connected to a source of the second transistor, and a drain of the second transistor is electrically connected to the capacitive element (more specifically, one capacitance electrode of a pair of capacitance electrodes constituting the capacitive element). The driving unit drives the first and second transistors. Typically, a gate of the first transistor is electrically connected to a first gate line which is a part of the driving unit, and a gate of the second transistor is electrically connected to a second gate line which is a part of the driving unit. When a first gate signal is supplied to the gate of the first transistor via the first gate line from a gate line driver circuit (or a row driver circuit) which is a part of the driving unit, the ON state and the OFF state of the first transistor are switched, and when a second gate signal is supplied to the gate of the second transistor via the second gate line, the ON state and the OFF state of the second transistor are switched. During operations of the semiconductor device according to the aspect of the invention, the data voltage to be applied to the capacitive element is applied to the data line from a data line driver circuit (or a column driver circuit) which is a part of the driving unit, for example, and the data voltage is applied to the capacitive element via the first and second transistors from the data line.

In this configuration, particularly, the driving unit drives the first and second transistors so that when the data voltage is applied to the capacitive element, both the first and second transistors are turned on, the second transistor is temporarily turned off after the timing at which both the first and second transistors are turned on and then turned on again, and the first transistor is turned off at the same timing at which the second transistor is temporarily turned off or after the timing and before the second transistor is turned on again. That is, according to this aspect of the invention, when the data voltage is applied to the capacitive element, first, both the first and second transistors are turned on by the driving unit. Accordingly, the data voltage is supplied to the capacitive element from the data line via the first and second transistors in the ON state. Next, the second transistor is temporarily turned off by the driving unit. The first transistor is maintained in the ON state or is turned off at the same time when the second transistor is temporarily turned off by the driving unit. When the second transistor is temporarily turned off, a feed-through voltage is generated due to a parasitic capacitance between the gate and the drain of the second transistor, and there is a concern that the voltage applied to the capacitance element is reduced (that is, there is a concern that the voltage applied to the capacitive element is reduced from the data voltage to be applied to the capacitive element by the feed-through voltage). However, according to this aspect of the invention, the second transistor is turned on after temporarily being turned off by the driving unit. In addition, when the second transistor is turned on again by the driving unit, the first transistor has been turned off by the driving unit. Therefore, a charge accumulated between the second transistor temporarily turned off and the first transistor in the OFF state can be supplied to the capacitive element via the second transistor when turned on, so that the voltage applied to the capacitive element can be increased (that is, the voltage applied to the capacitive element can be increased close to the data voltage or to almost or completely the same as the data voltage).

Therefore, in this configuration, the data voltage can be more reliably applied to the capacitive element via the first and second transistors from the data line.

In the semiconductor device according to this aspect of the invention, the driving unit may drive the first transistor so that the first transistor is turned off after the timing at which the second transistor is temporarily turned off and before the second transistor is turned on again.

In this configuration, during a period in which the second transistor is temporarily turned off and the first transistor is maintained in the ON state by the driving unit, the data voltage can be supplied to a source side (that is, between the first and second transistors) of the second transistor in the temporarily OFF state from the data line via the first transistor in the ON state. Therefore, when the second transistor is turned on again by the driving unit, the charge accumulated at the source side of the second transistor can be supplied to the capacitive element via the second transistor turned on, so that the voltage applied to the capacitive element can be more reliably increased.

In the semiconductor device according to this aspect of the invention, the driving unit may drive the first transistor so that the first transistor is turned off at the same timing at which the second transistor is temporarily turned off.

In this configuration, for example, as compared with the case where the first transistor is driven by the driving unit so that the first transistor is turned off after the timing at which the second transistor is temporarily turned off and before the second transistor is turned on again, a drive sequence for driving the first and second transistors can be simplified, so that a speed at which the data voltage is applied to the capacitive element can be increased.

In the semiconductor device according to this aspect of the invention, the data voltage may be constant from the timing at which both the first and second transistors are turned on to the timing at which the first transistor is turned off.

In this configuration, during the period from the timing at which both the first and second transistors are turned on to the timing at which the first transistor is turned off, the data voltage can be supplied to the source side of the second transistor via the first transistor in the ON state.

In the semiconductor device according to this aspect of the invention, the capacitive element and the first and second transistors may be provided at each intersection of n rows and m columns (here, m and n are natural numbers) of a matrix on a substrate, the data line may be provided for each of the columns, and the driving unit may have a first gate line electrically connected to a gate of the first transistor, and a second gate line electrically connected to a gate of the second transistor, the first and second gate lines being provided for each of the rows.

In this configuration, it is possible to realize a matrix apparatus for sequentially selecting a plurality of capacitive elements arranged in the matrix on the substrate. According to this aspect, even if parasitic capacitances of the plurality of the first and second transistors vary when manufactured, the data voltage can be more reliably applied to the capacitive element via the first and second transistors from the data line.

In the semiconductor device according to this aspect, the capacitive element may be a capacitor, a transistor, a liquid crystal element, an organic electroluminescence element, or an electrophoretic element.

In this configuration, a display apparatus of an active matrix drive type (that is, a liquid crystal apparatus, an organic EL apparatus, or an electrophoretic apparatus) can be realized. According to this aspect, even if parasitic capacitances of the first and second transistors vary when manufactured, the data voltage can be more reliably applied to the capacitive element via the first and second transistors from the data line, so that non-uniform display such as so-called “screen burn-in” can be reduced or prevented.

According to another aspect of the invention, there is provided a driving method of a semiconductor device, which drives a semiconductor device having a capacitive element, a data line to which a data voltage to be applied to the capacitive element is applied, a first transistor which is electrically connected between the capacitive element and the data line, and a second transistor which is electrically connected between the first transistor and the capacitive element, the driving method including: when the data voltage is applied to the capacitive element, driving the first and second transistors so that both the first and second transistors are turned on; driving the first and second transistors so that the second transistor is temporarily turned off after a timing at which both the first and second transistors are turned on; driving the first and second transistors so that the second transistor is turned on again after temporarily being turned off; and driving the first and second transistors so that the first transistor is turned off at the same timing at which the second transistor is temporarily turned off or after the timing and before the timing at which the second transistor is turned on again.

In this method, as in the semiconductor device according to the above aspect of the invention, the data voltage can be more reliably applied to the capacitive element via the first and second transistors from the data line.

In addition, various configurations which are the same as those of the semiconductor device according to the above aspect of the invention can be also appropriately applied to the driving method of the semiconductor device according to this aspect of the invention.

According to still another aspect of the invention, there is provided an electro-optical device having the semiconductor device (including various configurations thereof) according to the above aspect of the invention.

In this configuration, the semiconductor device according to the above aspects of the invention is included, so that various display apparatuses such as liquid crystal apparatuses, organic EL apparatuses, and electrophoretic apparatuses capable of displaying high-quality images can be realized.

According to yet another aspect of the invention, there is provided an electronic device having the electro-optical device (including various configurations thereof) according to the above aspect of the invention.

In the configuration, the above-mentioned electro-optical device according to the above aspect of the invention is included, so that various electronic devices such as projection-type display apparatuses, television sets, portable phones, portable audios, electronic organizers, word processors, view finder-type or direct-view monitor-type video tape recorders, workstations, video phones, POS terminals, touch panels, watches, electronic paper, and electronic notebooks can be realized.

The operations and other advantages of the invention are exhibited from the description of exemplary embodiments provided as follows.

### BRIEF DESCRIPTION OF THE DRAWINGS

The invention will be described with reference to the accompanying drawings, wherein like numbers reference like elements.

FIG. 1 is a diagram illustrating a configuration of a semiconductor device according to a first embodiment.

FIG. 2 is an equivalent circuit diagram of a unit circuit of the semiconductor device according to the first embodiment.

FIG. 3 is a first timing chart for explaining operations of the semiconductor device according to the first embodiment.

FIG. 4 is a second timing chart for explaining the operations of the semiconductor device according to the first embodiment.

FIG. 5 is a first schematic diagram for explaining the operations of the semiconductor device according to the first embodiment.

FIG. 6 is a second schematic diagram for explaining the operations of the semiconductor device according to the first embodiment.

FIG. 7 is a third schematic diagram for explaining the operations of the semiconductor device according to the first embodiment.

FIG. 8 is a fourth schematic diagram for explaining the operations of the semiconductor device according to the first embodiment.

FIG. 9 is a diagram illustrating a unit circuit of a semiconductor device according to a first modified example.

FIG. 10 is a diagram illustrating a unit circuit of a semiconductor device according to a second modified example.

FIG. 11 is a diagram illustrating a unit circuit of a semiconductor device according to a third modified example.

FIG. 12 is a first timing chart for explaining operations of the semiconductor device according to a second embodiment.

FIG. 13 is a second timing chart for explaining the operations of the semiconductor device according to the second embodiment.

FIG. 14 is a first schematic diagram for explaining the operations of the semiconductor device according to the second embodiment.

FIG. 15 is a second schematic diagram for explaining the operations of the semiconductor device according to the second embodiment.

FIG. 16 is a perspective view illustrating a configuration of a piece of electronic paper to which the semiconductor device according to the embodiments of the invention is applied.

FIG. 17 is a perspective view illustrating a configuration of an electronic notebook to which the semiconductor device according to the embodiments of the invention is applied.

### DESCRIPTION OF EXEMPLARY EMBODIMENTS

Hereinafter, exemplary embodiments of the invention will be described with reference to the accompanying drawings.

### First Embodiment

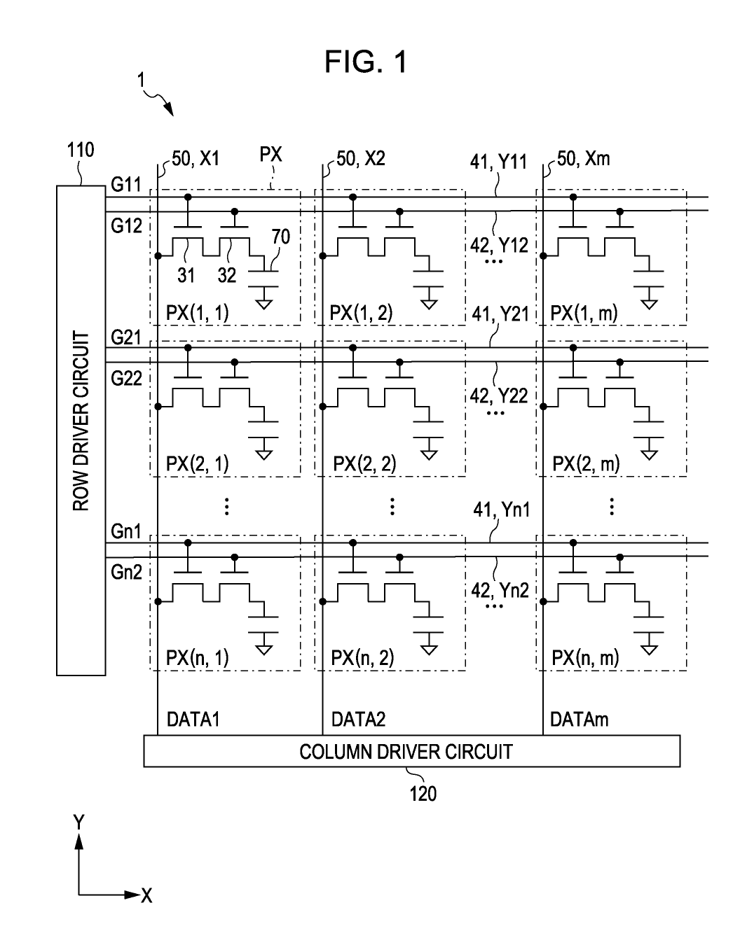

A semiconductor device according to a first embodiment will be described with reference to FIGS. 1 to 8.

First, the entire configuration of the semiconductor device according to this embodiment is described with reference to FIG. 1.

FIG. 1 is a diagram illustrating the configuration of the semiconductor device according to this embodiment.

In FIG. 1, the semiconductor device 1 according to this embodiment includes a plurality of unit circuits PX (that is, PX(1,1), PX(1,2), . . . , PX(n,m-1), PX(n,m)) arranged in a matrix (two-dimensional plane) with n rows and m columns (here, m and n are natural numbers), n first gate lines 41 (that is, first gate lines Y11, Y21, . . . , Yn1), n second gate lines 42 (that is, second gate lines Y12, Y22, . . . , Yn2), m data lines 50 (that is, data lines X1, X2, . . . , Xm), a row driver circuit 110, and a column driver circuit 120. The first gate lines 41, the second gate lines 42, the row driver circuit 110, and the column driver circuit 120 constitute an example of a “driving unit” according to the exemplary embodiments of the invention.

The n first gate lines 41 and the n second gate lines 42 extend in a row direction (that is, an X direction), and the m data lines 50 extend in a column direction (that is, a Y direction). At intersections of the n first gate lines 41 and the n second gate lines 42, and the m data lines 50, the corresponding unit circuits PX are disposed.

The row driver circuit 110 supplies first gate signals G1 (that is, first gate signals Gi1 (here, i=1, . . . , n)) to the first gate lines 41, and supplies second gate signals G2 (that is, second gate signals Gi2 (here, i=1, . . . , n)) to the second gate lines 42. Specifically, the row driver circuit 110 supplies the first gate signal G11 to the first gate line Y11, supplies the first gate signal G21 to the first gate line Y21, . . . , supplies the first gate signal Gn1 to the first gate line Yn1, supplies the second gate signal G12 to the second gate line Y12, supplies the second gate signal G22 to the second gate line Y22, . . . , and supplies the second gate signal Gn2 to the second gate line Yn2.

The column driver circuit 120 supplies data signals DATA (that is, data signals DATAk (here, k=1, . . . , m)) to the data lines 50. Specifically, the column driver circuit 120 supplies the data signal DATA1 to the data line X1, supplies the data signal DATA2 to the data line X2, . . . , and supplies the data signal DATAm to the data line Xm.

Each of the plurality of unit circuits PX includes a first transistor 31 and a second transistor 32 which are connected to each other in series, and a capacitive element 70.

The first transistor 31 is configured as an N-channel transistor using, for example, an amorphous semiconductor. The first transistor 31 has a gate electrically connected to the first gate line 41, a source electrically connected to the data line 50, and a drain electrically connected to a source of the second transistor 32. The first transistor 31 is switched between an ON state and an OFF state as the first gate signal G1 is supplied to the gate of the first transistor 31 from the row driver circuit 110 via the first gate line 41.

The second transistor 32 is configured as an N-channel transistor using, for example, an amorphous semiconductor. The second transistor 32 has a gate electrically connected to the second gate line 42, the source electrically connected to the drain of the first transistor 31, and a drain electrically connected to the capacitive element 70 (more specifically, one capacitance electrode of a pair of capacitance electrodes constituting the capacitive element 70). The second transistor 32 is switched between an ON state and an OFF state as the second gate signal G2 is supplied to the gate of the second transistor 32 from the row driver circuit 110 via the second gate line 42.

The capacitive element 70 is a capacitor having the pair of capacitance elements with a dielectric material therebetween. One capacitance electrode of the pair of capacitance electrodes constituting the capacitive element 70 is electrically connected to the drain of the second transistor 32. The other capacitance electrode of the pair of capacitance electrodes constituting the capacitive element 70 is electrically connected to a predetermined potential line to which a predetermined potential such as a ground potential is supplied. The capacitive element 70 is applied with a data voltage Vdata corresponding to the data signal DATA as the data signal DATA is supplied from the data line 50 via the first transistor 31 turned on and the second transistor 32 turned on.

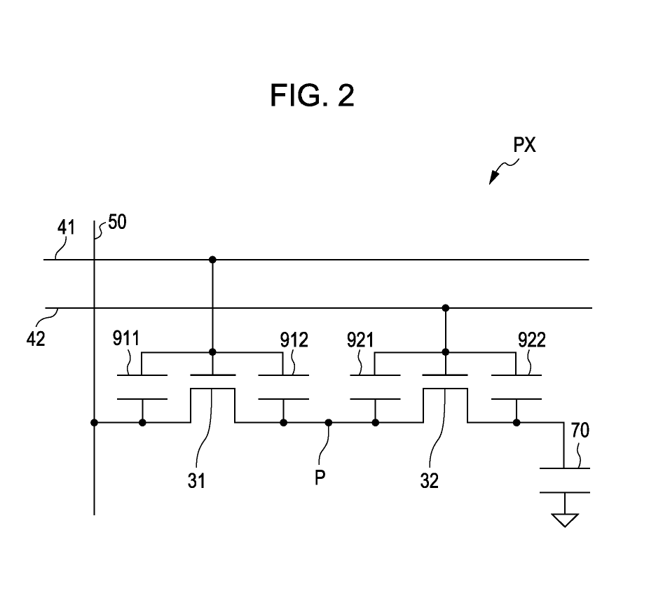

Next, operations of the semiconductor device according to this embodiment will be described with reference to FIGS. 2 to 8 in addition to FIG. 1. Hereinafter, operations performed by the semiconductor device according to this embodiment when the data voltage Vdata is applied to the capacitive element 70 will be described.

FIG. 2 is an equivalent circuit diagram of the unit circuit of the semiconductor device according to this embodiment.

In FIG. 2, the unit circuit PX includes the first transistor 31, the second transistor 32, and the capacitive element 70 as described above with reference to FIG. 1. A parasitic capacitance 911 exists between the gate and the source of the first transistor 31, a parasitic capacitance 912 exists between the gate and the drain of the first transistor 31, a parasitic capacitance 921 exists between the gate and the source of the second transistor 32, a parasitic capacitance 922 exists between the gate and the drain of the second transistor 32. Here, for the convenience of description, it is assumed that capacitance values of the parasitic capacitances 911, 912, 921, and 922 are the same and the capacitance value is referred to as Cpar. In addition, hereinafter, a capacitance value of the capacitive element 70 is denoted by Cload for the description.

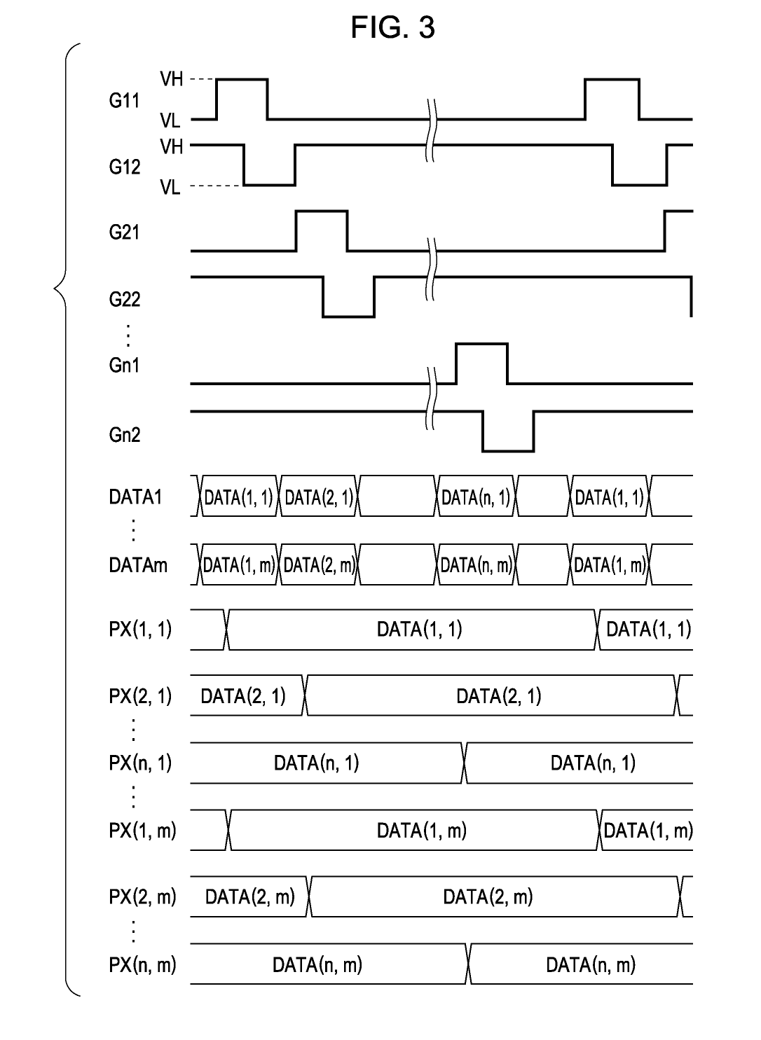

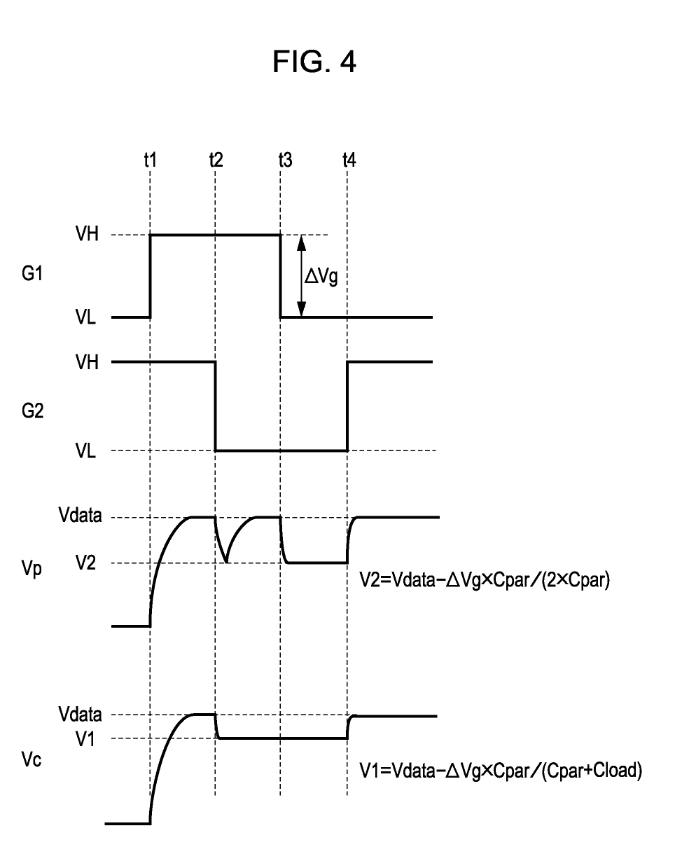

FIGS. 3 and 4 are timing charts for explaining the operations of the semiconductor device according to this embodiment.

In FIG. 3, changes over time in the first gate signals Gi1 (in other words, potentials of the first gate lines Yi1), the second gate signals Gi2 (in other words, potentials of the second gate lines Yi2), the data signals DATAk, and the data signals DATA (i,k) supplied to the unit circuits PX(I,k) are illustrated.

In FIG. 4, changes over time in the first and second gate signals G1 and G2, a voltage Vp at a point P illustrated in FIG. 2, and a voltage Vc applied to the one capacitance electrode (that is, the capacitance electrode electrically connected to the second transistor 32) of the capacitive element 70 are illustrated. In addition, the point P in FIG. 2 is a point between the drain of the first transistor 31 and the source of the second transistor 32.

As illustrated in FIGS. 3 and 4, each of the first gate signals G1 (that is, the first gate signals G11, G21, . . . , Gn1) and the second gate signals G2 (that is, the second gate signals G12, G22, . . . , Gn2) has any of a high-level potential VH and a low-level potential VL that is a potential lower than the high-level potential.

In this embodiment, particularly, when the data voltage Vdata corresponding to the data signal DATA is applied to the capacitive element 70, first, the first and second gate signals G1 and G2 are supplied to the first and second transistors 31 and 32 via the first and second gate lines 41 and 42 respectively from the row driver circuit 110 so as to cause both the first and second transistors 31 and 32 to be turned on.

That is, as illustrated in FIG. 4, when the data voltage Vdata corresponding to the data signal DATA is applied to the capacitive element 70, first, during a period from a time point t1 to a time point t2, both the first and second gate signals G1 and G2 have the high-level potential VH.

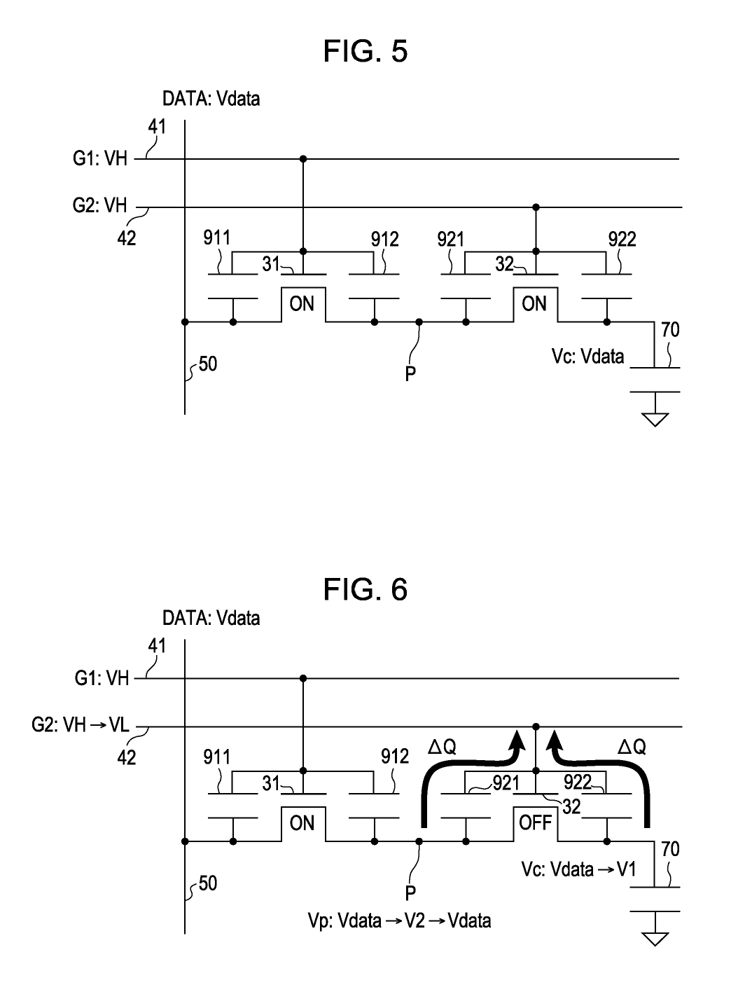

FIG. 5 is a schematic diagram for explaining the operations of the semiconductor device according to this embodiment and illustrates an operation state of the unit circuit PX during the period from the time point t1 to the time point t2.

As illustrated in FIG. 5, during the period from the time point t1 to the time point t2, since the first and second gate signals G1 and G2 both have the high-level potentials VH, both the first and second transistors 31 and 32 are in the ON state. Accordingly, the data signal DATA is supplied to the capacitive element 70 from the data line 50 via the first and second transistors 31 and 32 in the ON state, and thus the potential Vc of the one capacitance electrode of the capacitive element 70 becomes the data voltage Vdata (see FIG. 4). Here, the point P is electrically connected to the data line 50 by the first transistor 31 in the ON state, so that the voltage Vp at the point P becomes the data voltage Vdata (see FIG. 4).

Next, in FIG. 4, during a period from the time point t2 to a time point t3, while the first gate signal G1 is at the high-level potential VH, the second gate signal G2 has the low-level potential VL. That is, at the time point t2, the second gate signal G2 is changed from the high-level potential VH to the low-level potential VL, and the first gate signal G1 is maintained at the high-level potential VH.

FIG. 6 is a schematic diagram for explaining the operations of the semiconductor device according to this embodiment and illustrates the operation state of the unit circuit PX during the period from the time point t2 to the time point t3.

As illustrated in FIG. 6, during the period from the time point t2 to the time point t3, the first gate signal G1 has the high-level potential VH and the second gate signal G2 has the low-level potential VL, so that the first transistor 31 is in the ON state and the second transistor 32 is in the OFF state.

Here, as the second transistor 32 is turned off at the time point t2, a feed-through voltage is generated (in other words, a charge ΔQ moves from the drain side to the gate side of the second transistor 32) due to the parasitic capacitance 922 between the gate and the drain of the second transistor 32, and thus there is a concern that the potential Vc of the one capacitance electrode of the capacitive element 70 may be reduced to a potential V1 from the data voltage Vdata (see FIG. 4). Here, the potential V1 can be represented by Expression (1) as follows:

V1=Vdata−ΔVg×Cpar/(Cpar+Cload) (1)

where ΔVg=VH−VL

In addition, as the second transistor 32 is turned off at the time point t2, the voltage Vp at the point P is temporarily reduced from the data voltage Vdata to the potential V2 due to the feed-through voltage (in other words, the movement of the charge ΔQ from the source side to the gate side of the second transistor 32) that is generated due to the parasitic capacitance 921 between the gate and the source of the second transistor 32. However, since the point P is electrically connected to the data line 50 by the first transistor 31 in the ON state, the point P has the data voltage Vdata again (see FIG. 4). Here, the potential

V2 can be represented by Expression (2) as follows:

V2=Vdata×ΔVg×Cpar/(2×Cpar) (2)

Next, in FIG. 4, during a period from the time point t3 to a time point t4, both the first and second gate signals G1 and G2 have the low-level potential VL. That is, at the time point t3, the first gate signal G1 is changed from the high-level potential VH to the low-level potential VL, and the second gate signal G2 is maintained at the low-level potential VL.

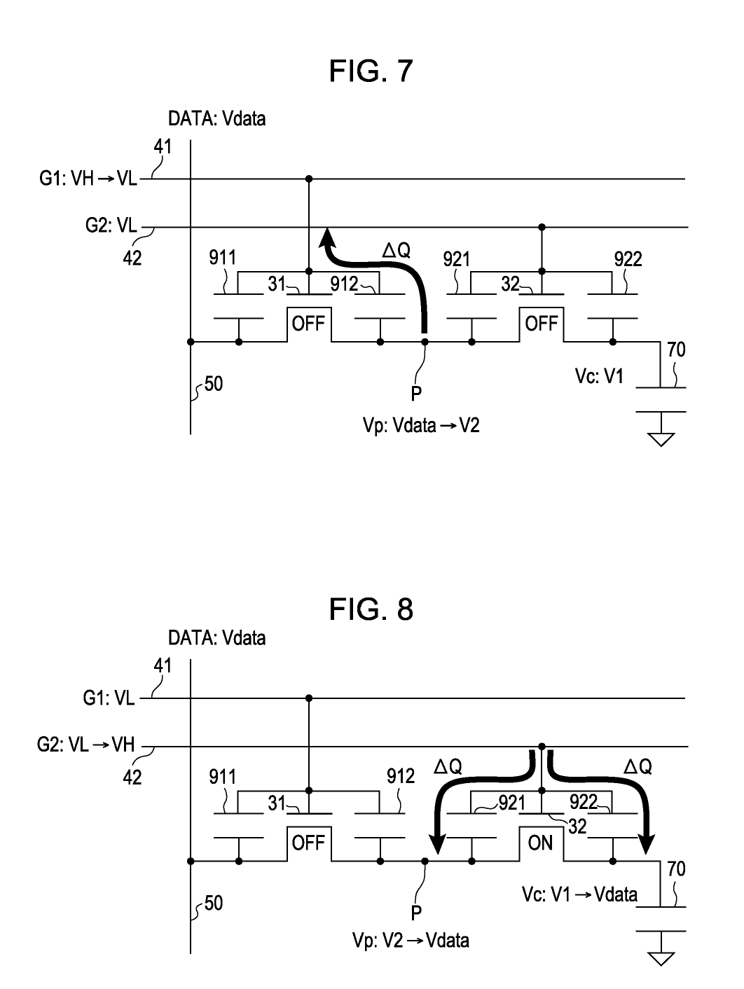

FIG. 7 is a schematic diagram for explaining the operations of the semiconductor device according to this embodiment and illustrates the operation state of the unit circuit PX during the period from the time point t3 to the time point t4.

As illustrated in FIG. 7, during the period from the time point t3 to the time point t4, both the first and second gate signals G1 and G2 have the low-level potential VL, so that both the first and second transistors 31 and 32 are in the OFF state. Accordingly, due to the first and second transistors 31 and 32 in the OFF state, the capacitive element 70 is electrically disconnected from the data line 50, and the potential Vc of the one capacitance electrode of the capacitive element 70 is maintained at the voltage V1 (see FIG. 4).

In addition, as the first transistor 31 is turned off at the time point t3, the voltage Vp at the point P is reduced from the data voltage Vdata to the potential V2 due to the feed-through voltage (in other words, the movement of the charge ΔQ from the drain side to the gate side of the first transistor 31) that is generated due to the parasitic capacitance 912 between the gate and the drain of the first transistor 31 (see FIG. 4). In addition, since the point P is electrically disconnected from the data line 50 by the first transistor 31 turned off, during the period from the time point t3 to the time point t4, the voltage Vp at the point P is maintained at the potential V2 (see FIG. 4).

Next, in FIG. 4, after the time point t4, while the first gate signal G1 is at the low-level potential VL, the second gate signal G2 has the high-level potential VH. That is, at the time point t4, the second gate signal G2 is changed from the low-level potential VL to the high-level potential VH, and the first gate signal G1 is maintained at the low-level potential VL.

FIG. 8 is schematic diagram for explaining the operations of the semiconductor device according to this embodiment, and illustrates the operation state of the unit circuit PX during a period after the time point t4.

As illustrated in FIG. 8, after the time point t4, as the first gate signal G1 has the low-level potential VL and the second gate signal G2 has the high-level potential

VH, the first transistor 31 is in the OFF state and the second transistor 32 is turned on.

Here, as the second transistor 32 is turned on at the time point t4, the voltage Vp at the point P is increased to the data voltage Vdata from the potential V2 due to the feed-through voltage (in other words, the movement of the charge ΔQ from the gate side to the source side of the second transistor 32) that is generated due to the parasitic capacitance 921 between the gate and the source of the second transistor 32 (see FIG. 4). Moreover, since the one capacitance electrode of the capacitive element 70 is electrically connected to the point P by the second transistor 32 turned on, the potential Vc of the one capacitance electrode of the capacitive element 70 is increased to the data voltage Vdata from the potential V1 (see FIG. 4). That is, the voltage applied to the capacitance element 70 which is temporarily reduced due to the feed-through voltage that is generated due to the parasitic capacitance 922 between the gate and the drain of the second transistor 32 can be increased to the data voltage Vdata to be applied.

As described above, according to this embodiment, when the data voltage Vdata is applied to the capacitive element 70, the first and second transistors 31 and 32 are driven by the row driver circuit 110 so that both the first and second transistors 31 and 32 are turned on at the time point t1, the second transistor 32 is turned on again at the time point t4 after temporarily being turned off at the point time t2, and the first transistor 31 is turned off at the time point t3 which is after the time point t2 at which the second transistor 32 is temporarily turned off and before the time point t4 at which the second transistor 32 is turned on again, so that the data voltage Vdata can be reliably applied to the capacitive element 70 via the first and second transistors 31 and 32 from the data line 50.

### FIRST MODIFIED EXAMPLE

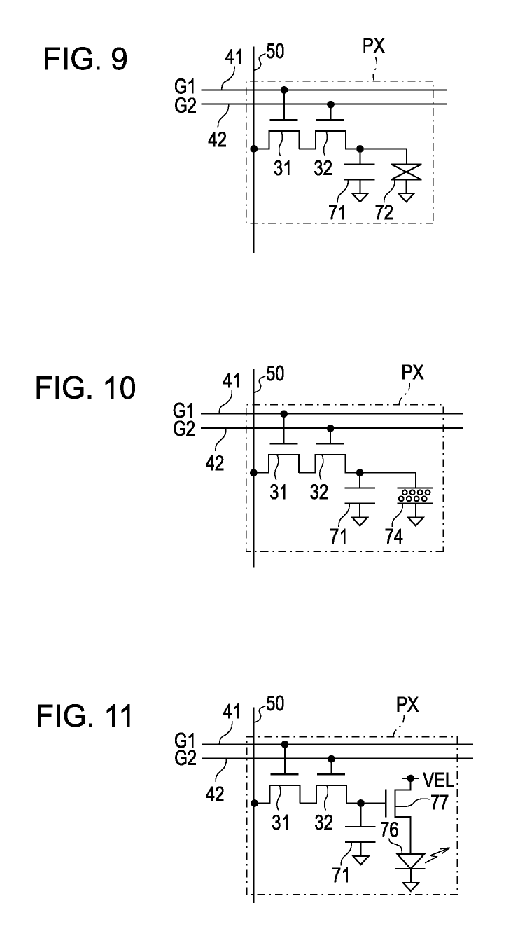

FIG. 9 is a diagram illustrating a unit circuit of a semiconductor device according to a first modified example.

As illustrated in FIG. 9, the unit circuit PX may include a storage capacitor 71 and a liquid crystal element 72 instead of the capacitive element 70 in the first embodiment described above with reference to FIG. 1. In this case, a liquid crystal display apparatus can be realized using the semiconductor device. Here, according to this modified example, even if parasitic capacitances of the first and second transistors 31 and 32 vary due to the variations in production, the data voltage can be reliably applied to the storage capacitor 71 which is a capacitive element and the liquid crystal element 72 via the first and second transistors 31 and 32 from the data line 50, so that non-uniform display such as so-called “screen burn-in” can be reduced or prevented.

### SECOND MODIFIED EXAMPLE

FIG. 10 is a diagram illustrating a unit circuit of a semiconductor device according to a second modified example.

As illustrated in FIG. 10, the unit circuit PX may include a storage capacitor 71 and an electrophoretic element 74 instead of the capacitive element 70 in the first embodiment described above with reference to FIG. 1. In this case, an electrophoretic display apparatus can be realized using the semiconductor device. Here, according to this modified example, even if parasitic capacitances of the first and second transistors 31 and 32 vary due to the variations in production, the data voltage can be reliably applied to the storage capacitor 71 which is a capacitive element and the electrophoretic element 74 via the first and second transistors 31 and 32 from the data line 50, so that non-uniform display can be reduced or prevented.

### THIRD MODIFIED EXAMPLE

FIG. 11 is a diagram illustrating a unit circuit of a semiconductor device according to a third modified example.

As illustrated in FIG. 11, the unit circuit PX may include a storage capacitor 71, an organic EL element 76, and a transistor 77 instead of the capacitive element 70 in the first embodiment described above with reference to FIG. 1. In this case, an organic EL display apparatus can be realized using the semiconductor device. Here, according to this modified example, even if parasitic capacitances of the first and second transistors 31 and 32 vary due to the variations in production, the data voltage can be reliably applied to the storage capacitor 71 which is a capacitive element and the organic EL element 76 via the first and second transistors 31 and 32 from the data line 50, so that non-uniform display can be reduced or prevented. In addition, in FIG. 11, the transistor 77 has a gate electrically connected to the storage capacitor 71, a source electrically connected to a predetermined potential VEL, and a drain electrically connected to the organic EL element 76.

### Second Embodiment

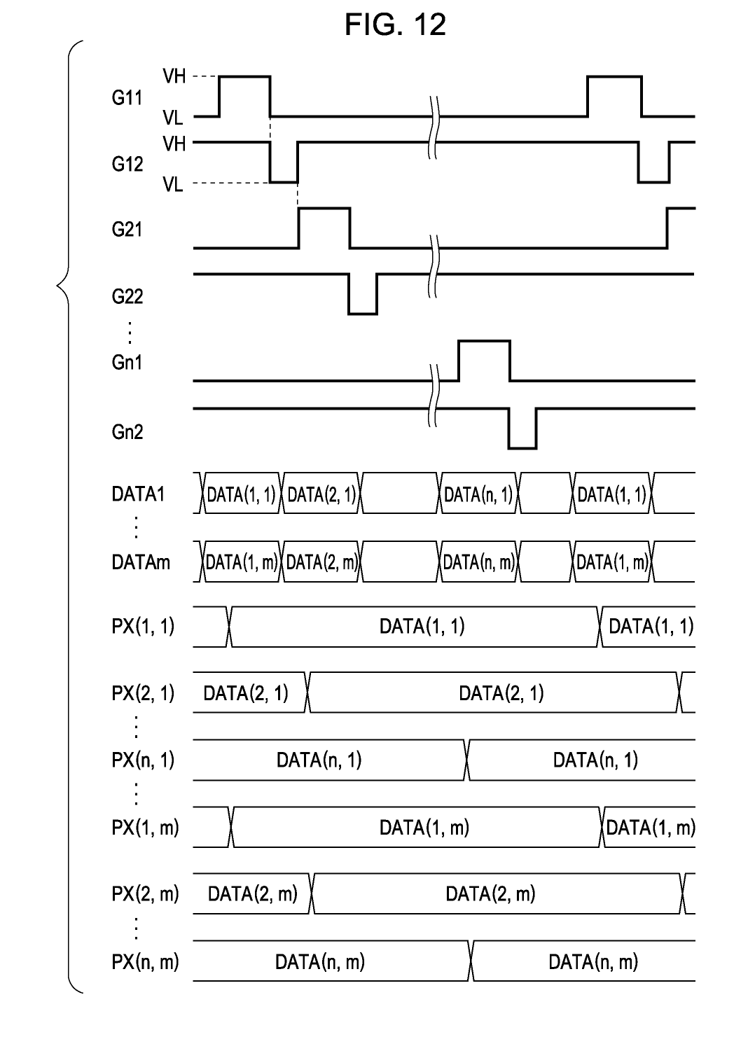

A semiconductor device according to a second embodiment will be described with reference to FIGS. 12 to 15. In addition, like components in FIGS. 12 to 15 which are the same as those according to the first embodiment described with reference to FIGS. 1 to 8 are denoted by like reference numerals and detailed description will be appropriately omitted.

In the semiconductor device according to the second embodiment, timings (in other words, a waveform of the second gate signal G2) at which the OFF state and the ON state of the second transistor 32 are switched are different from those according to the first embodiment described above, and other configurations are almost the same as those of the semiconductor device 1 according to the first embodiment described above.

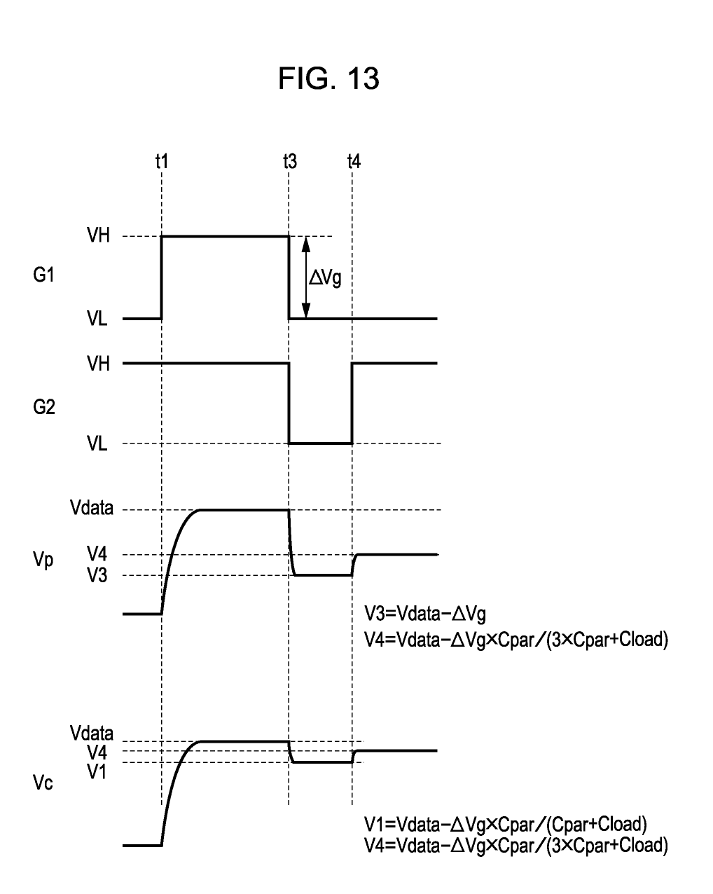

FIGS. 12 and 13 are timing charts for explaining operations of the semiconductor device according to the second embodiment.

FIG. 12 is a timing chart having the same purpose as that of FIG. 3 described above, and illustrates changes over time in the first gate signals Gi1, the second gate signals Gi2, the data signals DATAk, and the data signals DATA (I,k) supplied to the unit circuits PX(I,k) according to the second embodiment.

FIG. 13 is a timing chart having the same purpose as that of FIG. 4 described above, and illustrates changes over time in the first and second gate signals G1 and G2, the voltage Vp at the point P illustrated in FIG. 2, and the voltage Vc applied to the one capacitance electrode of the capacitive element 70 according to the second embodiment.

In FIGS. 12 and 13, according to this embodiment, particularly, after the time point t1 at which both the first and second gate signals G1 and G2 have the high-level potential VH, a timing at which the first gate signal G1 is changed from the high-level potential VH to the low-level potential VL is the same as a timing (both are the time point t3) at which the second gate signal G2 is changed from the high-level potential VH to the low-level potential VL. That is, according to this embodiment, particularly, after both the first and second transistors 31 and 32 are in the ON state (the time point t1), both the first and second transistors 31 and 32 are simultaneously turned off (the time point t3) and thereafter (the time point t4) the second transistor 32 is turned on again.

Specifically, according to this embodiment, when the data voltage Vdata corresponding to the data signal DATA is applied to the capacitive element 70, first, as in the first embodiment described above, the first and second gate signals G1 and G2 are supplied to the first and second transistors 31 and 32 via the first and second gate lines 41 and 42 from the row driver circuit 110 so that both the first and second transistors 31 and 32 are turned on.

That is, as illustrated in FIG. 13, when the data voltage Vdata corresponding to the data signal DATA is applied to the capacitive element 70, first, during a period from the time point t1 to the time point t3, both the first and second gate signals G1 and G2 have the high-level potential VH. Accordingly, as in the first embodiment described above, the potential Vc of the one capacitance electrode of the capacitive element 70 becomes the data voltage Vdata, and the voltage Vp at the point P becomes the data voltage Vdata.

Next, during the period from the time point t3 to the time point t4, both the first and second gate signals G1 and G2 have the low-level potential VL. That is, at the time point t3, both the first and second gate signals G1 and G2 are simultaneously changed from the high-level potential VH to the low-level potential VL.

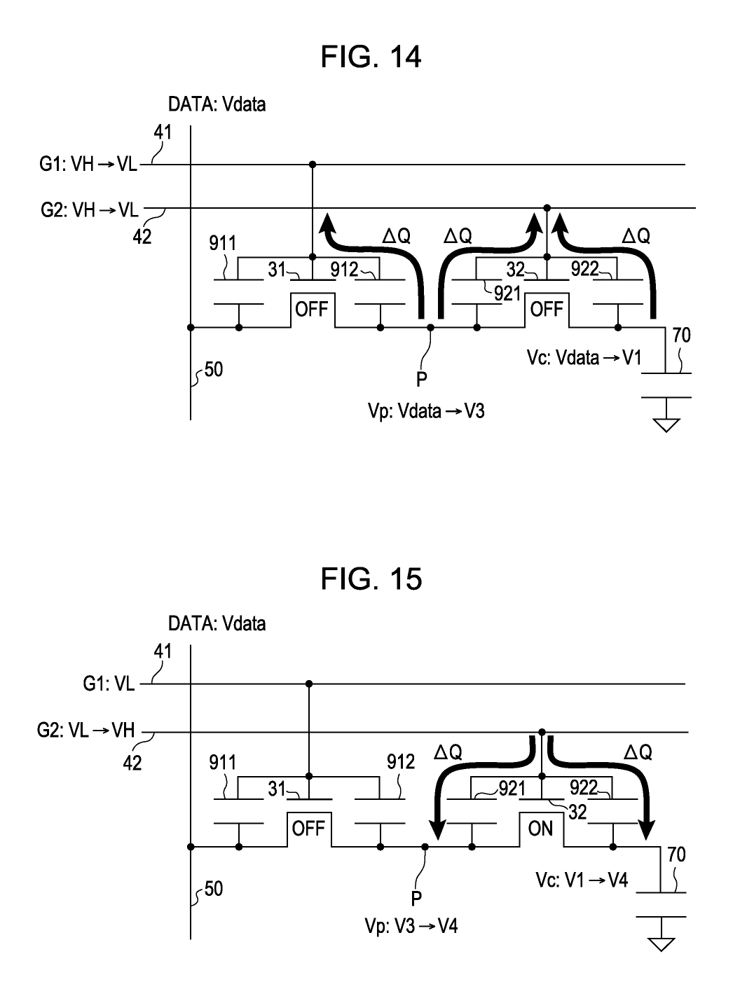

FIG. 14 is a schematic diagram for explaining the operations of the semiconductor device according to the second embodiment, and illustrates the operation state of the unit circuit PX during the period from the time point t3 to the time point t4.

As illustrated in FIG. 14, during the period from the time point t3 to the time point t4, as both the first and second gate signals G1 and G2 have the low-level potential VL, both the first and second transistors 31 and 32 are turned off.

Here, as both the first and second transistors 31 and 32 are turned off at the time point t3, there is a concern that the potential Vc of the one capacitance electrode of the capacitive element 70 may be reduced from the data voltage Vdata to the potential V1 due to the feed-through voltage that is generated (in other words, the movement of the charge ΔQ from the drain side to the gate side of the second transistor 32 occurs) due to the parasitic capacitance 922 between the gate and the drain of the second transistor 32 (see FIG. 13). The potential V1 can be represented by Expression (1) described above.

In addition, since both the first and second transistors 31 and 32 are turned off at the time point t3, the voltage Vp at the point P is reduced from the data voltage Vdata to the potential V3 due to the feed-through voltage (in other words, the movement of the charge ΔQ from the drain side to the gate side of the first transistor 31) that is generated due to the parasitic capacitance 912 between the gate and the drain of the first transistor 31, and the feed-through voltage (in other words, the movement of the charge ΔQ from the source side to the gate side of the second transistor 32) that is generated due to the parasitic capacitance 921 between the gate and the source of the second transistor 32. Here, the potential V3 can be represented by Expression (3) as follows:

V3=Vdata−ΔVg (3)

Next, in FIG. 13, after the time point t4, while the first gate signal G1 is at the low-level potential VL, the second gate signal G2 has the high-level potential VH. That is, at the time point t4, the second gate signal G2 is changed from the low-level potential VL to the high-level potential VL, and the first gate signal G1 is maintained at the low-level potential VL.

FIG. 15 is a schematic diagram for explaining the operations of the semiconductor device according to this embodiment, and illustrates the operation state of the unit circuit PX during the period after the time point t4.

As illustrated in FIG. 15, after the time point t4, since the first gate signal G1 has the low-level potential VL and the second gate signal G2 has the high-level potential VH, the first transistor 31 is in the OFF state, and the second transistor 32 is turned on.

Here, as the second transistor 32 is turned on at the time point t4, the voltage Vp at the point P is increased from the potential V3 to a potential V4 due to the feed-through voltage (in other words, the movement of the charge ΔQ from the gate side to the source side of the second transistor 32) that is generated due to the parasitic capacitance 921 between the gate and the source of the second transistor 32 (see FIG. 13). Here, the potential V4 can be represented by Expression (4) as follows:

V4=Vdata−ΔVg×Cpar/(3×Cpar+Cload) (4)

Moreover, since the one capacitance electrode of the capacitive element 70 is electrically connected to the point P by the second transistor 32 turned on, the potential Vc of the one capacitance electrode of the capacitive element 70 is increased from the potential V1 to the potential V4 (see FIG. 13).

As such, according to this embodiment, the potential Vc of the one capacitance electrode of the capacitive element 70, which is reduced to the potential V1 due to the feed-through voltage that is generated due to the parasitic capacitance 922 between the gate and drain of the second transistor 32 can be increased to the potential V4 (that is, the potential Vc of the one capacitance electrode of the capacitive element 70 can be close to the data voltage Vdata to be applied).

Moreover, according to this embodiment, particularly, the first and second transistors 31 and 32 are driven so that after both the first and second transistors 31 and 32 are in the ON state at the time point t1, both the first and second transistors 31 and 32 are simultaneously turned off at the time point t3, and thereafter the second transistor 32 is turned on again at the time point t4. Therefore, compared to the first embodiment described above, a drive sequence for driving the first and second transistors 31 and 32 can be simplified, thereby increasing a speed at which the data voltage Vdata is applied to the capacitive element 70.

### Electronic Device

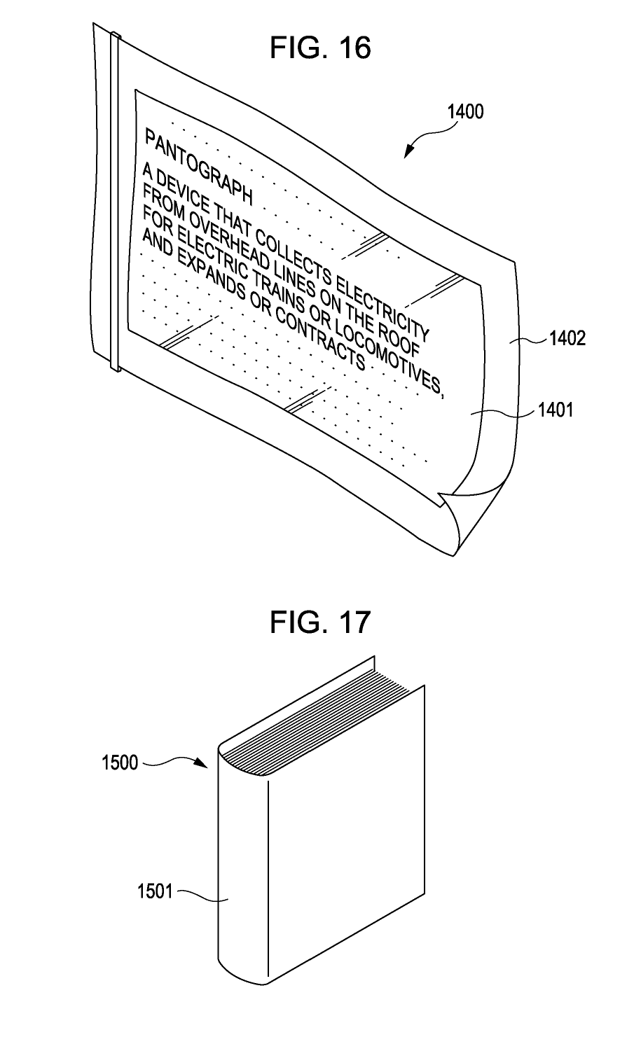

Next, an electronic device which applies the semiconductor device described above will be described with reference to FIGS. 16 and 17. Hereinafter, a case where the above-mentioned semiconductor device is configured as an electrophoretic display apparatus according to the second modified example described above and applied to a piece of electronic paper or an electronic notebook will be exemplified.

FIG. 16 is a perspective view illustrating a configuration of a piece of electronic paper 1400.

As illustrated in FIG. 16, the piece of electronic paper 1400 includes the above-mentioned semiconductor device as a display unit 1401. The piece of electronic paper 1400 has flexibility and a main body 1402 made of a rewritable sheet having the same texture and flexibility as existing paper.

FIG. 17 is a perspective view illustrating a configuration of an electronic notebook 1500.

As illustrated in FIG. 17, the electronic notebook 1500 is configured by binding a plurality of sheets of the electronic paper 1400 illustrated in FIG. 16 and set in a cover 1501. The cover 1501 has a display data input unit (not shown) for inputting display data sent from, for example, an external device. Accordingly, in a state where the sheets of the electronic paper are bound, displayed contents can be changed or updated in response to the display data.

The piece of electronic paper 1400 and the electronic notebook 1500 described above have the semiconductor device described above and thus can display images with high quality.

In addition, the semiconductor device according to the embodiments described above can be applied to display units of electronic devices such as watches, portable phones, and portable audio devices.

The invention is not limited to the above-described embodiments and can be suitably modified without departing from the spirit and scope of the invention that can be read from the entire claims and the specification, and the semiconductor device, the driving method of the semiconductor device, the electro-optical device, and the electronic device with such modifications are included in the technical scope of the invention.

What is claimed is:

1. A semiconductor device comprising:
a capacitive element;
a data line to which a data voltage to be applied to the capacitive element is applied;
a first transistor which is electrically connected between the capacitive element and the data line;
a second transistor which is electrically connected between the first transistor and the capacitive element; and
a driving unit which drives the first and second transistors so that when the data voltage is applied to the capacitive element, both the first and second transistors are turned on, the second transistor is temporarily turned off, after a timing at which both the first and second transistors are turned on, and then turned on again, and the first transistor is turned off at the same timing at which the second transistor is temporarily turned off or after the timing and before the second transistor is turned on again.

2. The semiconductor device according to claim 1, wherein the driving unit drives the first transistor so that the first transistor is turned off after the timing at which the second transistor is temporarily turned off and before the second transistor is turned on again.

3. The semiconductor device according to claim 1, wherein the driving unit drives the first transistor so that the first transistor is turned off at the same timing at which the second transistor is temporarily turned off.

4. The semiconductor device according to claim 1, wherein the data voltage is constant from the timing at which both the first and second transistors are turned on to the timing at which the first transistor is turned off.

5. The semiconductor device according to claim 1,
wherein the capacitive element and the first and second transistors are provided at each intersection of n rows and m columns (here, m and n are natural numbers) of a matrix on a substrate,
wherein the data line is provided for each of the columns, and
wherein the driving unit has a first gate line electrically connected to a gate of the first transistor, and a second gate line electrically connected to a gate of the second transistor, the first and second gate lines being provided for each of the rows.

6. The semiconductor device according to claim 1, wherein the capacitive element is one of a capacitor, a transistor, a liquid crystal element, an organic electroluminescence element, and an electrophoretic element.

7. A driving method of a semiconductor device, which drives a semiconductor device having a capacitive element, a data line to which a data voltage to be applied to the capacitive element is applied, a first transistor which is electrically connected between the capacitive element and the data line, and a second transistor which is electrically connected between the first transistor and the capacitive element, the driving method comprising:
when the data voltage is applied to the capacitive element,
driving the first and second transistors so that both the first and second transistors are turned on;
driving the first and second transistors so that the second transistor is temporarily turned off after a timing at which both the first and second transistors are turned on;
driving the first and second transistors so that the second transistor is turned on again after temporarily being turned off; and
driving the first and second transistors so that the first transistor is turned off at the same timing at which the second transistor is temporarily turned off or after the timing and before the timing at which the second transistor is turned on again.

8. An electro-optical device having the semiconductor device according to claim 1.

9. An electro-optical device having the semiconductor device according to claim 2.

10. An electro-optical device having the semiconductor device according to claim 3.

11. An electro-optical device having the semiconductor device according to claim 4.

12. An electro-optical device having the semiconductor device according to claim 5.

13. An electro-optical device having the semiconductor device according to claim 6.

14. An electronic device having the electro-optical device according to claim 8.

15. An electronic device having the electro-optical device according to claim 9.

16. An electronic device having the electro-optical device according to claim 10.

17. An electronic device having the electro-optical device according to claim 11.

18. An electronic device having the electro-optical device according to claim 12.

19. An electronic device having the electro-optical device according to claim 13.
